(19) United States
(12) Patent Application Publication
(10) Pub. No.: US 2020/0264229 A1
(43) Pub. Date: Aug. 20, 2020

(54) SOC IMMINENT FAILURE PREDICTION USING AGING SENSORS

(71) Applicant: QUALCOMM Incorporated, San Diego, CA (US)

(72) Inventors: Uttkarsh WARDHAN, Bangalore (IN); Madan M. KRISHNAPPA, Bangalore (IN); Shih-Hsin Jason HU, San Diego, CA (US); Min CHEN, San Marcos, CA (US)

(21) Appl. No.: 16/277,543

(22) Filed: Feb. 15, 2019

(51) Int. Cl. G01R 31/28; G01R 31/00; H03K 3/03

(52) U.S. Cl. CPC G01R 31/2879; H03K 3/0315; G01R 31/2882; G01R 31/007

(57) ABSTRACT

Aspects of the present disclosure provide techniques for predicting a failure of an integrated circuit, which may include receiving first aging sensor data during an idle state of the integrated circuit; determining a voltage compensation value based on the first aging sensor data; comparing a new voltage value based on the voltage compensation value to a threshold operating voltage; determining the new operating voltage value exceeds the threshold operating voltage; determining a warning state for the integrated circuit; receiving second aging sensor data during the idle state of the integrated circuit; receiving stored aging sensor data from an aging sensor data repository; comparing the second aging sensor data to the stored aging sensor data; determining that the second aging sensor data is inconsistent with the stored aging sensor data; and determining a danger state for the integrated circuit.

### INTRODUCTION

Aspects of the present disclosure relate to predicting the imminent failure of an integrated circuit, such as a system on a chip (SoC), using aging sensors.

SoCs used in electronic devices are frequently designed to work continuously without a failure for a relatively short lifespan, such as three to four years. While seemingly brief, the expected lifespan (sometimes measured as a mean time between failure, or MTBF) of such SoCs is often based on the expected life of the electronic device in which the SoCs reside. For example, many consumer mobile electronic devices, such as mobile phones, tend to be used for just a few years before being replaced by a new device.

However, the explosive growth of computerization of all sorts of products means that existing assumptions about sufficient SoC lifespans are no longer holding true. For example, modern automobiles may include tens or even hundreds of systems using integrated circuits, such as SoCs. But unlike mobile electronic devices, automobiles are expected to have significantly longer service lifespans (e.g., ten to fifteen years).

Moreover, as automobiles become increasingly computerized, their susceptibility to major faults becomes more and more related to the reliability of the underlying electronics. For example, a fault in a single SoC in an automobile may significantly degrade the functionality of the automobile, or even render the automobile entirely non-functional, because of the complexities and cross-dependencies of the integrated systems onboard. Further, because such SoCs may control critical safety systems, the tolerance for failures is significantly lower than in other types of products, such as mobile phones. Thus, SoCs with expected lifespans significantly shorter than the expected service life of the products in which they reside creates significant problems for product designers.

These problems are particularly difficult to solve for a variety of technical and economic reasons. For example, as node sizes in integrated circuits, such as SoCs, have decreased, the reliability of the integrated circuits have likewise decreased. This is because the material tolerances become tighter, less forgiving, and naturally more prone to failure due to inherent material properties. Thus, designing SoCs for significantly longer lifespans results in significantly more cost, which negatively affects the cost-competitiveness of the products incorporating such SoCs.

One potential solution, which balances cost and durability considerations, is to accurately predict the imminent failure of an SoC so that it can be replaced before causing significant failures in the product. For example, an SoC in a critical automobile system might be proactively replaced relatively easily and inexpensively if its failure is predictable. Unfortunately, electronic devices are not designed with such predictive failure capabilities. And even then, the ability to predict a failure of an SoC with many individual circuit elements is inherently difficult.

Accordingly, what is needed are systems and methods for predicting imminent failures in integrated circuits, such as SoCs.

### BRIEF SUMMARY

Certain implementations provide a method for predicting a failure of an integrated circuit. In one example, a method includes receiving first aging sensor data during an idle state of the integrated circuit; determining a voltage compensation value based on the first aging sensor data; comparing a new voltage value based on the voltage compensation value to a threshold operating voltage; determining the new operating voltage value exceeds the threshold operating voltage; determining a warning state for the integrated circuit based on determining the new operating voltage value exceeds the threshold operating voltage; receiving second aging sensor data during the idle state of the integrated circuit; receiving stored aging sensor data from an aging sensor data repository; comparing the second aging sensor data to the stored aging sensor data; determining that the second aging sensor data is inconsistent with the stored aging sensor data; and determining a danger state for the integrated circuit based on determining that the second aging sensor data is inconsistent with the stored aging sensor data.

Additional implementations include a processing system configured for performing the methods for predicting a failure of an integrated circuit described herein. Further implementations provide a computer-readable medium comprising instructions that, when executed by a processing system, cause the processing system to perform the methods for predicting a failure of an integrated circuit described herein.

The following description and the related drawings set forth in detail certain illustrative features of one or more implementations.

### BRIEF DESCRIPTION OF THE DRAWINGS

The appended figures depict certain aspects of the one or more implementations and are therefore not to be considered limiting of the scope of this disclosure.

FIG. 1 depicts an example flow for aging sensor-based failure prediction.

FIG. 2 depicts a system using aging sensors for failure prediction.

FIG. 3 depicts an example method for predicting a failure of an integrated circuit.

FIG. 4 depicts an example processing system, which may be configured to perform methods described herein.

To facilitate understanding, identical reference numerals have been used, where possible, to designate identical elements that are common to the drawings. It is contemplated that elements and features of one implementation may be beneficially incorporated in other implementations without further recitation.

### DETAILED DESCRIPTION

Aspects of the present disclosure provide apparatuses, methods, processing systems, and computer readable mediums for predicting the imminent failure of an integrated circuit, such as a system on a chip (SoC), using aging sensors.

Consumer products are increasingly reliant on computerized systems. For example, the automotive industry is developing ever more complex, computer-controlled systems for existing technologies, such as internal combustion engine control systems, emissions systems, and safety systems, as well as for emerging technologies, such as hybrid and fully electronic vehicle control systems and self-driving systems. Though automobiles are generally getting more complex as the number of computer-controlled systems integrated into the automobiles increases, automobiles are also getting more reliable and therefore being kept in service longer. Automobile manufacturers may now expect their products to be in use for ten or more years on average.

Because automobiles are staying in service for longer lifespans, automobile manufacturers are in need of improved systems and methods for predicting failures in the myriad computerized systems in automobiles so that consumer experiences with the automobiles are positive and safe. This is especially true for certain automotive technologies, such as safety systems and self-driving systems. For such systems, automobile manufacturers may set stringent failure metrics, including allowing no unpredicted failures. Thus, analyzing and preempting catastrophic failures in critical automobile systems is indispensable.

Notably, while automobile systems are used as one example throughout this disclosure, the systems and methods described herein are equally applicable to predicting failures in integrated circuits, such as SoCs, in any sort of computerized product. For example, unmanned and manned aircraft, watercraft, and spacecraft systems may benefit from improved failure prediction in many of the same ways as automobiles. As another example, home security systems and industrial control and monitoring systems may implement improved failure prediction as described herein so that maintenance can be handled proactively in a planned and safe manner, with minimal impact on regular operation. Similarly, server and data centers may implement improved failure prediction as described herein to prevent data loss and operational downtime due to critical component failures. As yet another example, Internet of Things (IoT) sensors implementing improved failure prediction as described herein may be integrated into other systems to predict operational failures of non-digital components, for example, by judging the stress and aging that the non-digital components have gone through over their lifetimes. These are just a few examples, and many other exist.

### Aging Detection Techniques for Digital Integrated Circuitry Using Ring Oscillators

Integrated circuits experience many different types of aging-related degradation. In order to maximize the chance of predicting a failure before it happens, it is beneficial to identify aspects of an integrated circuit that are likely to fail first consistently. In this regard, negative bias temperature instability (NBTI) has proven to be one of the fastest sources of degradation in integrated circuits, such as SoCs. Consequently, aging sensors may use NBTI as a leading indicator to predict integrated circuit failures.

However, detecting aging in digital circuitry is challenging because a majority of the digital logic in any given integrated circuit is synchronous (in its respective clock domain). Generally, as elements of an integrated circuit age, their process corner characteristics degrade, which causes the integrated circuit to become “slower”. However, synchronous digital circuitry does not directly reflect effects of degradation by virtue of its synchronicity.

Further, some integrated circuits include voltage control circuits that increase operating voltages to compensate for the slower timing characteristics. Unfortunately, aging-based voltage compensation tends to mask the effects of integrated circuit degradation because, for a while at least, the integrated circuit will obfuscate the aging related slowing down with parameter-based (e.g., operating voltage) speeding up. Moreover, such compensation may actually hasten the aging process. For example, increased operating voltages may increase thermal and piezo-electric stresses, which may lead to increased insulation degradation between different metal layers and the oxide layers in transistor gates of an integrated circuit.

However, some circuitry in integrated circuits, such as SoCs, is asynchronous. For example, various ring oscillators in an integrated circuit may run asynchronously. Unlike synchronous circuitry, the performance characteristics of asynchronous ring oscillators in various circuit elements may change in detectable ways as the integrated circuit ages. For example, timing parameters of the various ring oscillator elements in the integrated circuit may be impacted by aging, which may in-turn affect ring oscillator counts (where a count is a number of cycles of the ring oscillator in a given timeframe). In fact, while voltage control circuitry may mask aging-related slowing as described above, components of the voltage control circuitry, such as one or more ring oscillators, may provide indications that can be used to predict failures despite the overall performance compensations. Thus, failure prediction capability may be based on existing structures without the need for additional circuit elements in some implementations, which is beneficial to power consumption, chip space allocation, cost, and other aspects.

In some implementations, a core power reduction ring oscillator (CPR-RO) in an integrated circuit may be used as (or as part of) an aging sensor. CPR-ROs may be particularly well-suited for this role because their oscillations depend on process-voltage-temperature (PVT) conditions of the integrated circuit and reflect changes to these conditions accurately. Thus, counts of these oscillations can be indicative of the aging condition of the integrated circuit—especially when compared over time.

### Example Aging Sensor-Based Failure Prediction Flow

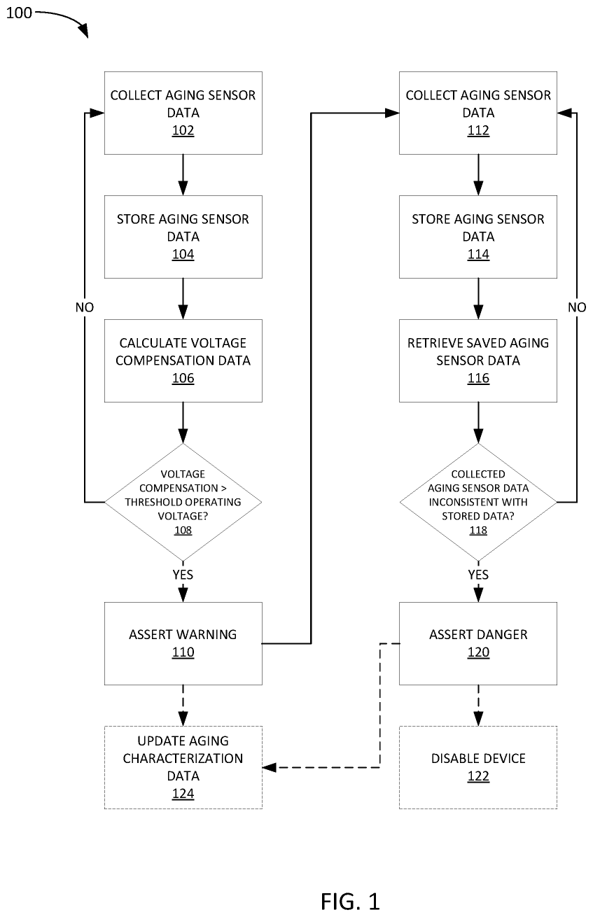

FIG. 1 depicts an example flow 100 for aging sensor-based failure prediction.

Flow 100 begins at step 102 with collecting aging sensor data. In some implementations, aging sensor data is only collected when an integrated circuit, such as an SoC, or the device in which is resides, is in a certain state, such as in an idle state or during boot-up. This may help ensure that the aging sensor data is objectively comparable. For example, load on a processing core in an SoC may cause a voltage or speed increase, which may create skewed aging data.

In some implementations, the aging sensor may include or may be a ring oscillator, and the aging sensor data may be ring oscillator counts from the aging sensor. In some implementations, the ring oscillator may be a core power reduction ring oscillator (CPR-RO).

Flow 100 then proceeds to step 104 with storing the aging sensor data. For example, the aging sensor data may be stored in a repository in a local or otherwise accessible memory. In some implementations, the memory may be a part of an SoC in which the aging sensor resides.

Flow 100 then proceeds to step 106 with calculating voltage compensation data. For example, the aging sensor data (e.g., ring oscillator count) may indicate a certain amount of slowing, which may be offset by increasing an operating voltage. Thus, the voltage compensation data may include commands, parameters, or other data that causes a voltage source (e.g. a power source connected to the SoC) to provide more or less operating voltage. In some cases, the voltage compensation data may be retrieved based on pre-existing tables or relationship curves, i.e., an open-loop process, whereas in other cases the voltage compensation may be based on a closed-loop feedback (e.g., where a voltage compensation is applied and a resulting timing is measured iteratively until the resulting timing is within a threshold).

Flow 100 then proceeds to step 108 where the voltage compensation is compared to a threshold operating voltage. For example, a current voltage may be 1.1V and the voltage compensation may provide a relative voltage change (e.g., +0.2) or an absolute voltage target (e.g., 1.3V). In either case, if the result of the voltage compensation does not exceed a threshold operating voltage (e.g., 1.5V), then the flow returns to step 102 to collect more aging sensor data. However, if the result of the voltage compensation does exceed a threshold operating voltage (e.g., 1.25V), then a warning condition may be asserted at step 110.

The warning condition asserted at step 110 may generally indicate that the SoC is nearing failure and should be replaced to avoid an in-service failure. Asserting a warning condition at step 110 may include, for example, setting a condition flag within the SoC, as well as transmitting messages, parameters, settings, or other indications to one or more ancillary systems. In an automobile example, the warning condition may be displayed as a warning message or indicator on a dash instrument panel, or on another display device, or through an application that interfaces with the automobile, or any combination thereof. Further, details regarding the warning condition may be queried by, for example, an on-board diagnostic scanner (e.g., OBD-II) or other computer system capable of data exchange with the automobile's electronic system.

Optionally, as indicated by the broken lines, aging characterization data may be updated at step 124 based on the asserted warning. For example, information regarding the SoC, the aging sensor data, etc. may be stored so that an aging profile related to the SoC may be developed over time based on multiple observations. In some cases, the aging characterization data may be stored in a remote repository so that a manufacturer (e.g., of the SoC) may analyze the performance of fielded SoC and better predict failures. Aging characterization data may be used to form aging profiles for SoCs so that another feature may be used in a failure prediction model.

Collectively, steps 102-110 may be referred to as a first state or stage of the failure prediction flow example in FIG. 1. Once a warning is asserted at step 110, the prediction flow moves to a second state or stage (in this example), as depicted in steps 112-120 (and optionally 122).

The second phase of failure prediction in this implementation begins with collecting more aging sensor data at step 112 (as above with step 102).

Flow 100 then proceeds to step 114 with storing the aging sensor data (as above in step 104).

Flow 100 then proceeds to step 116 with retrieving saved aging sensor data (e.g., from an aging sensor data repository as discussed above). Note that the retrieved aging sensor data at step 116 may include more aging data than just that collected in step 112. For example, the retrieved aging sensor data at step 116 may include data for the entire working life of the SoC, or some relevant subset of that data. For example, the aging sensor data may be retrieved based on a look-back parameter, such as retrieving data for the last week, or month, etc.

Flow 100 then proceeds to step 118 where the aging sensor data collected at step 112 is compared against the aging sensor data retrieved at step 116 to determine if the newly collected data is inconsistent with the stored data. As SoCs age and get near failure, the aging sensor data may become erratic. Thus, step 118 seeks to identify this inconsistent behavior as a sign of imminent failure.

Inconsistency of the collected data (step 112) versus the retrieved data (step 116) may be determined in many ways. For example, a basic metric such as a difference in collected data versus an average (or moving average) of the retrieved data may be determined and compared to a difference threshold. As an alternative, a statistical metric may be calculated based on the retrieved data, such as a standard deviation, and compared to the collected data to determine if it exceeds the standard deviation, or some metric based on the standard deviation. As yet another alternative, the stored aging data may be used to train a machine learning model, which may take the collected data as input and output a probability of imminent failure. In such cases, the machine learning model may be trained based on aging characterization data stored for the same or similar SoCs, as discussed above with respect to step 124. Notably, these are just a few examples, and many others are possible.

If at step 118, the collected aging sensor data is determined to be consistent with the stored aging data, then flow 100 returns to step 112. However, if at step 118, the collected aging sensor data is determined to be inconsistent with the stored aging data, then flow 100 proceeds to step 120.

At step 120, a danger condition is asserted. The danger condition asserted at step 120 may generally indicate that the SoC is expected to fail imminently and should be replaced immediately to avoid an in-service failure. As above with the warning condition at step 110, asserting a danger condition at step 120 may include setting a condition flag within the SoC, as well as transmitting messages, parameters, or other indications to one or more ancillary systems.

Further, after asserting the danger condition at step 120, further steps may be taken to protect the device. For example, the SoC may be disabled immediately, or set to not boot again. This may consequently disable the device in which the SoC resides. For example, in an automobile context, an SoC within an in-car entertainment system module may be prevented from booting with other system when the automobile is started once a danger condition is asserted. This prohibition, or others, may last until the SoC is replaced or otherwise serviced.

Finally, as above, the danger condition and related SoC data may be stored with other aging characterization data at step 124 so as to develop aging profiles for the SoC and/or device in which the SoC resides. As above, an aging profile may allow for additional method of predicting warning or danger conditions beyond those discussed in the example of flow 100.

### Example System Using Aging Sensors for Prediction of SoC Failure

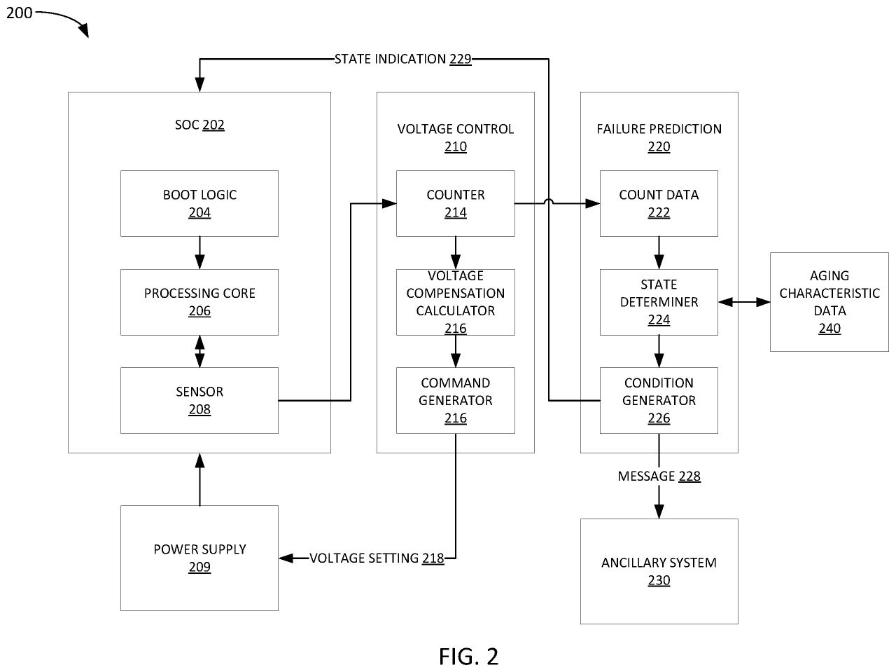

FIG. 2 depicts a system 200 using aging sensors for failure prediction.

System 200 includes an SoC 202, which includes boot logic 204 that controls aspects of booting SoC 202. As described in further detail below, boot logic 204 may include parameters settable by a failure prediction circuit to prevent SoC 202 from booting once an imminent failure is predicted by failure prediction circuit 220.

SoC 202 also includes a processing core 206, which may comprise one or more processors, each including one or more processing cores. In some cases, processing core 206 may include different types of processors, such as CPUs, GPUs, and other special purpose processors.

SoC 202 also includes an aging sensor 208. Aging sensor 208 may include one or more ring oscillators, such as core power reduction ring oscillators. In some implementations, aging sensor 208 is configured to measure aging based on negative bias temperature instability (NBTI). Aging sensor 208 may output one or more counts, such as counts related to oscillations of its one or more ring oscillators.

System 200 also includes a voltage control circuit 210. Notably, in the depicted implementation, voltage control circuit 210 is separate from SoC 202, but in other implementations, SoC 202 may have an integral voltage control circuit.

Voltage control circuit 210 includes a counter 214, which in this implementation receives count data from aging sensor 208 in SoC 202. Counter 214 outputs count data to voltage compensation calculator 216, which uses the count data to determine whether a voltage compensation (e.g., a decrease or increase in an operating voltage) needs to be made.

Based on the calculation performed by voltage compensation calculator 216, a command may be generated by command generator 216. In the depicted implementation, command generator 216 generates a voltage setting command 218 and transmits it to power supply 209. As described above, voltage setting command 218 may take many forms, such as a relative voltage change, an absolute voltage setting, and others. Power supply 209 may, in-turn, change the voltage supplied to SoC 202 based on voltage setting 218.

System 200 also includes a failure prediction circuit 220. Here again, in the depicted implementation, failure prediction circuit 220 is separate from SoC 202, but in other implementations, SoC 202 may have an integral failure prediction circuit.

Failure prediction circuit 220 includes a count data repository 222, where count data (e.g., ring oscillator count data) is received from counter 214 and stored. Count data 222 is used by state determiner 224 to determine a state of SoC 202.

State determiner 224 may, for example, determine that SoC 202 is in an operational state, a warning state, or a danger state as described above with respect to FIG. 1. Here, an operational state would indicate the absence of a warning or danger state. Other states may be defined and determined by state determiner 224.

As described above, in some implementations state determiner 224 may determine a state solely based on count data received derived from an aging sensor, such as aging sensor 208. However, in other implementations, state determiner may also consider aging characteristic data 240. In some cases, both count data 222 and aging characteristic data 240 may be inputs to a model configured to output a state determination. Other model inputs are likewise possible.

In some implementations, aging characterization data 240 may be generated using testing techniques, such as high-temperature open loop/high-voltage (HTOL). HTOL testing may speed up aging of SoCs, such as SoC 202, which can generate a baseline of aging data for characterization. This may be particularly useful in testing of new integrated circuit designs.

State determiner 224 passes determined state data to condition generator 226, which shares the state data with other aspects of system 200. For example, condition generator 226 may format a message to an ancillary system so that a warning message may be displayed to a user, manufacturer, technician, or the like. As described above, in an automobile example, an ancillary system could be dash warning indicator, warning message on a dash or other display screen, message to a mobile device associated with a user of the automobile, or any other electronic system configured to display information related to the automobile to a user.

Condition generator 226 may also transmit a setting, parameter, or other indication to SoC based on the determined condition. For example, a warning state indication 229 may be transmitted to SoC 202 in order to affect its performance in some way meant to extend the lifespan of SoC 202. As another example, a danger state indication may be transmitted to SoC 202 in order to affect the boot logic so that SoC 202 cannot be booted again. These are just a few examples, and many others exist.

Though not depicted in this example, failure prediction circuit 220 may be used to monitor and predict failures for more than one SoC or other integrated circuit element.

System 200 advantageously allows for the opportunity to replace SoC 202 before a failures can occur, which means that SoC 202 may be used in systems where high reliability is required and which are in service for a period much longer than the lifespan of SoC 202.

Moreover, system 200 need not require any hardware overhead because existing circuit elements, such as ring oscillators in sensor 208 used by voltage control circuit 210 may also be used by failure prediction circuit 220. In other words, the additional capability comes without the need for additional chip space and cost. Similarly, system 200 requires minimal software overhead. SoC may be configured to already record aging data from sensor 208 (e.g., from a ring oscillator) during a conventional boot-up sequence. Thus, software overhead may be limited to additional aging sensor check functions, comparison functions, and notification functions.

### Example Method for Predicting Failure of an Integrated Circuit

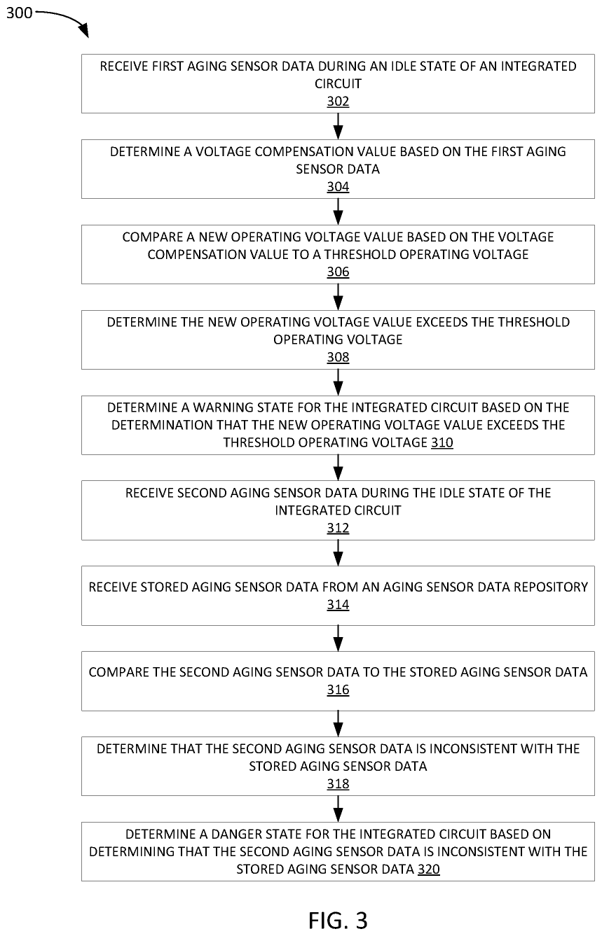

FIG. 3 depicts an example method 300 for predicting a failure of an integrated circuit. In some implementations, the integrated circuit comprises a system on a chip (SoC). Further in some implementations, the SoC is configured to control an automobile system.

Method 300 begins at step 302 with receiving first aging sensor data during an idle state of an integrated circuit. In some implementations, the first aging sensor data is based on a ring oscillator count, such as a core power reduction ring oscillator.

As discussed above, an idle state, or a boot state, or any other state where active processes are not causing processing load are preferable for measuring aging.

Method 300 then proceeds to step 304 with determining a voltage compensation value based on the first aging sensor data. As described above, the voltage compensation value may be a relative value or an absolute value. In yet other implementations, the voltage compensation may simply be a directional indication, such as a step increase or step decrease, without any ordinal value.

Method 300 then proceeds to step 306 with comparing a new operating voltage value based on the voltage compensation value to a threshold operating voltage. The new operating voltage value may be determined based on applying the voltage compensation value to a current operating voltage. For example, the current operating voltage may be 1.2V and the voltage compensation value may be +0.2V so that the new operating voltage value would be 1.4V. The threshold operating voltage is a voltage over which the integrated circuit is not allowed to operate. In some implementations, the threshold operating voltage may be referred to alternatively as an open loop voltage.

Method 300 then proceeds to step 308 with determining the new operating voltage value exceeds the threshold operating voltage.

Method 300 then proceeds to step 310 with determining a warning state for the integrated circuit based on determining the new operating voltage value exceeds the threshold operating voltage.

Method 300 then proceeds to step 312 with receiving second aging sensor data during the idle state of the integrated circuit. Notably, the aging sensor data received at step 312 can be, but need not be, from the same idle state as the first aging sensor data received in step 302.

Method 300 then proceeds to step 314 with receiving stored aging sensor data from an aging sensor data repository. As described above, the aging sensor data repository may be stored locally with the integrated circuit, or remotely, but otherwise accessible by the integrated circuit. For example, the aging sensor data repository could be stored in a memory integral to an SoC, or in a memory in a device in which the SoC is integrated and which is accessible to the SoC.

Method 300 then proceeds to step 316 with comparing the second aging sensor data to the stored aging sensor data. The comparison may take the form of simple mathematical operations (e.g., taking a difference) or more complex statistical calculations, such as generating averages, moving averages, medians, standard deviations, variances, and the like with respect to the stored aging sensor data.

Method 300 then proceeds to step 318 with determining that the second aging sensor data is inconsistent with the stored aging sensor data.

As described above, determining that the second aging sensor data is inconsistent with the stored aging sensor data may involve use of metrics, such as a difference in second aging sensor data versus an average (or moving average) of the stored aging sensor data being compared to a difference threshold. Statistical metrics may also be calculated and compared to determine if the metrics exceeds a threshold. And as further described above, the stored aging data may be used to train a machine learning model, which may take the second aging data as input and output a probability of imminent failure. In some cases, the machine learning model may be trained based on aging characterization data stored for the same or similar integrated circuits. Notably, these are just a few examples, and many others are possible.

Method 300 then proceeds with determining a danger state for the integrated circuit based on determining that the second aging sensor data is inconsistent with the stored aging sensor data. A danger state may indicate that it is expected that the integrated circuit will fail within some threshold period of time. Imminent failure might mean within a minute, hour, day, week, or the like.

The method of claim 3, wherein determining that the second aging sensor data is inconsistent with the stored aging sensor data comprises: determining that a difference between the second aging sensor data and the stored aging sensor data exceeds a difference threshold.

Though not depicted in FIG. 3, in some implementations, method 300 may further include setting a parameter for the integrated circuit, wherein the parameter is configured to prevent the integrated circuit from booting again. For example, as described above with respect to FIG. 2, a state indication, may be sent to an integrated circuit to cause the boot logic to be changed in order to prevent booting of the integrated circuit. Notably, this is just one example, and many other possibilities for preventing the integrated circuit from booting are equally applicable.

Further, in some implementations method 300 may further include transmitting a state message to an ancillary system, wherein the state message is configured to be displayed on a display device. As described above, the ancillary system may include indicators or a display so that the condition of the integrated circuit is communicated to a user of the device in which the integrated circuit reside.

### Example Processing System for Performing Methods for Predicting a Failure of an Integrated Circuit

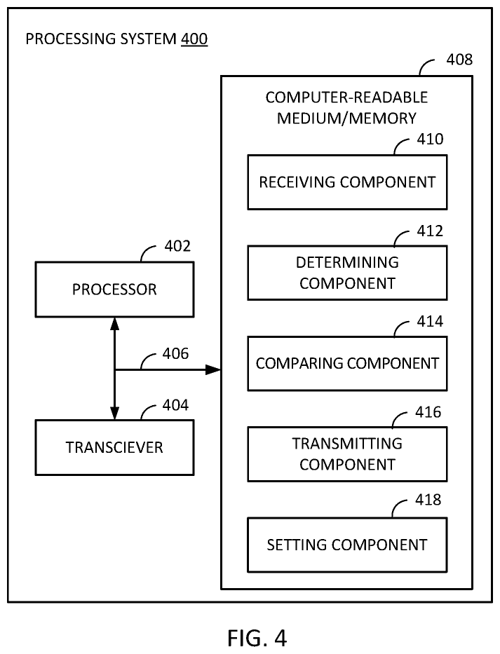

FIG. 4 depicts an example processing system 400, which may be configured to perform methods such as those described above with respect to FIGS. 1 and 2.

Processing system 400 includes processor 402 connected to transceiver 404 and memory 408 by way of bus 406.

Processor 402 may be any sort of processor capable of executing instructions and implementing the various components stored in memory 408.

Transceiver 404 may be configured for transmitting from and receiving data at processing system 400, such as from other systems in data communication with processing system 400.

In this example, memory 408 (which is a computer-readable medium) includes receiving component 410, determining component 412, comparing component 414, transmitting component 416, and setting component 418, which are individually configured to perform the various aspects of the methods described above with respect to FIGS. 1 and 2.

Notably, processing system 400 is just one example, and many other configurations are possible.

The preceding description is provided to enable any person skilled in the art to practice the various implementations described herein. The examples discussed herein are not limiting of the scope, applicability, or implementations set forth in the claims. Various modifications to these implementations will be readily apparent to those skilled in the art, and the generic principles defined herein may be applied to other implementations. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The following claims are not intended to be limited to the implementations shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method for predicting a failure of an integrated circuit, comprising:
receiving first aging sensor data during an idle state of the integrated circuit;
determining a voltage compensation value based on the first aging sensor data;
comparing a new voltage value based on the voltage compensation value to a threshold operating voltage;
determining the new operating voltage value exceeds the threshold operating voltage;
determining a warning state for the integrated circuit based on determining the new operating voltage value exceeds the threshold operating voltage;
receiving second aging sensor data during the idle state of the integrated circuit;
receiving stored aging sensor data from an aging sensor data repository;
comparing the second aging sensor data to the stored aging sensor data;
determining that the second aging sensor data is inconsistent with the stored aging sensor data; and
determining a danger state for the integrated circuit based on determining that the second aging sensor data is inconsistent with the stored aging sensor data.

2. The method of claim 1, wherein the first aging sensor data is based on a ring oscillator count.

3. The method of claim 2, wherein the ring oscillator count is based on a core power reduction ring oscillator.

4. The method of claim 3, wherein determining that the second aging sensor data is inconsistent with the stored aging sensor data comprises: determining that a difference between the second aging sensor data and the stored aging sensor data exceeds a difference threshold.

5. The method of claim 3, further comprising:
setting a parameter for the integrated circuit,
wherein the parameter is configured to prevent the integrated circuit from booting again.

6. The method of claim 3, further comprising:
transmitting a state message to an ancillary system,
wherein the state message is configured to be displayed on a display device.

7. The method of claim 3, wherein:
the integrated circuit comprises a system on a chip (SoC), and
the SoC is configured to control an automobile system.

8. A processing system, comprising:
a memory comprising computer-executable instructions;
a processor configured to execute the computer-executable instructions and cause the processing system to perform a method for predicting a failure of an integrated circuit, the method comprising:
receiving first aging sensor data during an idle state of the integrated circuit;
determining a voltage compensation value based on the first aging sensor data;
comparing a new voltage value based on the voltage compensation value to a threshold operating voltage;
determining the new operating voltage value exceeds the threshold operating voltage;
determining a warning state for the integrated circuit based on determining the new operating voltage value exceeds the threshold operating voltage;
receiving second aging sensor data during the idle state of the integrated circuit;
receiving stored aging sensor data from an aging sensor data repository;
comparing the second aging sensor data to the stored aging sensor data;
determining that the second aging sensor data is inconsistent with the stored aging sensor data; and
determining a danger state for the integrated circuit based on determining that the second aging sensor data is inconsistent with the stored aging sensor data.

9. The processing system of claim 8, wherein the first aging sensor data is based on a ring oscillator count.

10. The processing system of claim 9, wherein the ring oscillator count is based on a core power reduction ring oscillator.

11. The processing system of claim 10, wherein determining that the second aging sensor data is inconsistent with the stored aging sensor data comprises: determining that a difference between the second aging sensor data and the stored aging sensor data exceeds a difference threshold.

12. The processing system of claim 10, wherein the method further comprises:
setting a parameter for the integrated circuit,
wherein the parameter is configured to prevent the integrated circuit from booting again.

13. The processing system of claim 10, wherein the method further comprises:
transmitting a state message to an ancillary system,
wherein the state message is configured to be displayed on a display device.

14. The processing system of claim 10, wherein:
the integrated circuit comprises a system on a chip (SoC), and
the SoC is configured to control an automobile system.

15. A non-transitory computer-readable medium comprising instructions that, when executed by a processor of a processing system, cause the processing system to perform a method for predicting a failure of an integrated circuit, the method comprising:
receiving first aging sensor data during an idle state of the integrated circuit;
determining a voltage compensation value based on the first aging sensor data;
comparing a new voltage value based on the voltage compensation value to a threshold operating voltage;
determining the new operating voltage value exceeds the threshold operating voltage;
determining a warning state for the integrated circuit based on determining the new operating voltage value exceeds the threshold operating voltage;
receiving second aging sensor data during the idle state of the integrated circuit;
receiving stored aging sensor data from an aging sensor data repository;
comparing the second aging sensor data to the stored aging sensor data;
determining that the second aging sensor data is inconsistent with the stored aging sensor data; and
determining a danger state for the integrated circuit based on determining that the second aging sensor data is inconsistent with the stored aging sensor data.

16. The non-transitory computer-readable medium of claim 15, wherein the first aging sensor data is based on a ring oscillator count.

17. The non-transitory computer-readable medium of claim 16, wherein the ring oscillator count is based on a core power reduction ring oscillator.

18. The non-transitory computer-readable medium of claim 17, wherein determining that the second aging sensor data is inconsistent with the stored aging sensor data comprises: determining that a difference between the second aging sensor data and the stored aging sensor data exceeds a difference threshold.

19. The non-transitory computer-readable medium of claim 17, wherein the method further comprises:
setting a parameter for the integrated circuit,
wherein the parameter is configured to prevent the integrated circuit from booting again.

20. The non-transitory computer-readable medium of claim 17, wherein the method further comprises:
transmitting a state message to an ancillary system,
wherein:
the state message is configured to be displayed on a display device,
the integrated circuit comprises a system on a chip (SoC), and
the SoC is configured to control an automobile system.
